(19) United States
(12) Patent Application Publication
(10) Pub. No.: US 2009/0020887 A1
(43) Pub. Date: Jan. 22, 2009

(54) SEMICONDUCTOR APPARATUS AND MANUFACTURING METHOD THEREOF

(75) Inventors: Shigeru MIZUNO, Nagano (JP); Takashi KURIHARA, Nagano (JP); Akinori SHIRAISHI, Nagano (JP); Kei MURAYAMA, Nagano (JP); Mitsutoshi HIGASHI, Nagano (JP)

Correspondence Address: DRINKER BIDDLE & REATH (DC), 1500 K STREET, N.W., SUITE 1100, WASHINGTON, DC, 20005-1209, US

(73) Assignee: Shinko Electric Industries Co., Ltd., Nagano-shi (JP)

(21) Appl. No.: 12/174,192

(22) Filed: Jul. 16, 2008

(30) Foreign Application Priority Data
Jul. 20, 2007 (JP) 2007-190030

(51) Int. Cl. H01L 23/52; H01L 21/00

(52) U.S. Cl. 257/777; 438/109; 257/E23.141; 257/E21.001

(57) ABSTRACT

In a semiconductor apparatus in which plural semiconductor elements are stacked, metal wires whose one ends are connected to electrode terminals of the semiconductor elements are extended to the side surfaces of the semiconductor elements in an abutment state and the metal wires extended to the side surfaces of the semiconductor elements are bonded to a side surface wiring formed on side surfaces of the semiconductor elements by a conductive paste containing conductive particles.

### TECHNICAL FIELD

The present disclosure relates to a semiconductor apparatus and a manufacturing method thereof, and more particularly to a semiconductor apparatus in which plural semiconductor elements are stacked through an adhesive layer so that each of the electrode terminal formation surfaces on which electrode terminals of the semiconductor elements are formed is turned in the same direction, and a manufacturing method thereof.

### RELATED ART

A semiconductor apparatus capable of achieving density growth by arranging semiconductor elements 100, 100 in three dimensions as described in a semiconductor apparatus shown in FIG. 11 has been considered with capacity and density growth of a recent semiconductor apparatus. In the semiconductor apparatus shown in FIG. 11, the semiconductor elements 100, 100 are stacked on one surface of a wiring substrate 102 through adhesive layers 104, 104, and wire bonding between pads of the wiring substrate 102 and electrode terminals disposed in the vicinity of each of the peripheral edges of the semiconductor elements 100, 100 is performed by gold wires 106, 106, . . . and the pads are electrically connected to the electrode terminals.

However, as shown in FIG. 11, when the pads of the wiring substrate 102 are electrically connected to the electrode terminals disposed in the vicinity of each of the peripheral edges of the semiconductor elements 100, 100 by the wire bonding, it becomes necessary to seal the gold wires 106, 106, . . . etc. with a resin in order to protect the gold wires 106, 106, . . . and the finally obtained semiconductor apparatus becomes larger.

As a result of this, in order to miniaturize the semiconductor apparatus in which plural semiconductor elements are arranged in three dimensions, a semiconductor apparatus 200 shown in FIG. 12 has been proposed in the following Patent Reference 1.

In the semiconductor apparatus 200 shown in FIG. 12, side surface wirings 206, 206, . . . for electrically connecting pads of a wiring substrate 202 to each of the electrode terminals of each of the semiconductor elements 204, 204, . . . are formed on side surfaces of the plural semiconductor elements 204, 204, . . . stacked on the one surface of the wiring substrate 202.

Also, a semiconductor apparatus 300 shown in FIG. 13 has been proposed in the following Patent Reference 2. In this semiconductor apparatus 300, plural semiconductor elements 306, 306 in which electrode terminals 302, 302 formed on both surfaces are electrically connected by loop-shaped metal wires 304 are stacked so that the metal wires 304 make contact with each other.

[Patent Reference 1] Japanese Patent Application Publication No. 2002-76167

[Patent Reference 2] Japanese Patent Application Publication No. 2001-223323

According to the semiconductor apparatus 200 shown in FIG. 12 and the semiconductor apparatus 300 shown in FIG. 13, miniaturization can be achieved as compared with the semiconductor apparatus shown in FIG. 11.

However, as the semiconductor elements 204, 204, . . . constructing the semiconductor apparatus 200 shown in FIG. 12, the semiconductor element in which the electrode terminal is formed on the side surface must be used and a normal semiconductor element in which an electrode terminal is formed on the one surface of the semiconductor element cannot be used.

Moreover, the side surface wirings 206, 206, . . . of the semiconductor apparatus 200 are formed on the side surfaces of the semiconductor elements 204, 204, . . . after the semiconductor elements 204, 204, . . . are stacked on the one surface of the circuit substrate 202 using a liftoff method and a vapor deposition method, and a manufacturing step of the semiconductor apparatus 200 is made troublesome.

On the other hand, when a semiconductor element in which an electrode terminal is formed on the one surface is used as the semiconductor elements 204, 204, . . . , it is necessary to make a rewiring which is connected to the electrode terminal at one end and extended to the side surface of the semiconductor element, and the manufacturing step of the semiconductor apparatus 200 is made troublesome more.

Also, in the semiconductor apparatus 300 shown in FIG. 13, the semiconductor element 306 in which the electrode terminals 302, 302 are formed on both surfaces must be used and a normal semiconductor element in which an electrode terminal is formed on only the one surface cannot be used.

Further, in electrical connection by contact between the mutual loop-shaped metal wires 304, 304 for connecting the electrode terminals 302, 302 formed on both surfaces of the semiconductor element 306, the metal wires 304, 304 tend to become a non-contact state easily due to vibration etc. and are lacking in reliability. As a result of this, it becomes necessary to seal the portions of the metal wires 304, 304 with a resin in order to hold a state of contact between the metal wires 304, 304, and there is a limit to miniaturization of the semiconductor apparatus.

Moreover, it is extremely difficult to form the loop-shaped metal wires 304 for connecting the electrode terminals 302, 302 formed on both surfaces of the semiconductor element 306 by a wire bonder, so that a manufacturing step of the semiconductor apparatus is complicated.

Therefore, in the related-art semiconductor apparatus in which a normal semiconductor element in which an electrode terminal is formed on the one surface cannot be used and a manufacturing step of the semiconductor apparatus is complicated.

### SUMMARY

Exemplary embodiments of the present invention provide a semiconductor apparatus capable of preventing complication of a manufacturing step of the semiconductor apparatus and using a normal semiconductor element in which an electrode terminal is formed on its one surface, and a manufacturing method of the semiconductor apparatus.

The present inventors et al. found that connection between side surface wiring and an electrode terminal of a semiconductor element can be made surely and easily by stacking plural semiconductor elements in which metal wires whose one ends are connected to the electrode terminals are extended to the side surfaces and bonding the portions of the metal wires extended to the side surfaces of these semiconductor elements to the side surface wiring formed on side surfaces of the stacked semiconductor elements by a conductive paste.

That is, an exemplary embodiment of the invention resides in a semiconductor apparatus in which plural semiconductor elements are stacked, which comprises:

a plurality of semiconductor elements which are stacked;

metal wires, each of which is connected to each of electrode terminals of the semiconductor elements at one end and is extended to the side surfaces of the semiconductor elements; and

a side surface wiring formed on the side surfaces of the stacked semiconductor elements by a conductive paste containing conductive particles,

wherein at least a part of the metal wires extended to the side surfaces of the semiconductor elements is bonded to the side surface wiring.

Also, an exemplary embodiment of the invention is a manufacturing method of a semiconductor apparatus, which comprising:

stacking a plurality of semiconductor elements in which metal wires are connected to electrode terminals at one ends are extended to side surfaces of the semiconductor elements, through an adhesive layer; and

applying a conductive paste the side surfaces of the stacked semiconductor elements and forming a side surface wiring to which at least a part of the metal wires extended to the side surfaces of the semiconductor elements is bonded.

In such exemplary embodiments of inventions, a metal wire can be extended in a state of being abutted on at least a side surface of a semiconductor element by installing the semiconductor element on a metal foil so that an electrode terminal formation surface on which the electrode terminal is formed faces to an upper surface; performing a wire bonding of the metal wire by a shooting up method including connecting the other end of the metal wire to the metal foil and then connecting the one end of the metal wire to the electrode terminal of the semiconductor element; rotating the semiconductor element so as to abut the metal wire on the side surface of the semiconductor element; and cutting the metal wire in a state of extending the metal wire to the side surface of the semiconductor element. Alternatively, a metal wire can be extended in a state of being abutted on at least a side surface of a semiconductor element by installing the semiconductor element on a metal foil so that an electrode terminal formation surface on which the electrode terminal is formed faces to an upper surface; performing a wire bonding of the metal wire by a shooting up method including connecting the other end of the metal wire to the metal foil and then connecting the one end of the metal wire to the electrode terminal of the semiconductor element; sliding the semiconductor element so as to abut the metal wire on the side surface of the semiconductor element; and cutting the metal wire in a state of extending the metal wire to the side surface of the semiconductor element.

Also, a metal wire can be extended to a surface opposite to an electrode terminal formation surface beyond a side surface of a semiconductor element by installing the semiconductor element on a metal foil so that an electrode terminal formation surface on which the electrode terminal is formed faces to an upper surface; performing a wire bonding of the metal wire by a shooting up method including connecting the other end of the metal wire to the metal foil and then connecting the one end of the metal wire to the electrode terminal of the semiconductor element; rotating the semiconductor element is rotated so as to abut the metal wire on the side surface of the semiconductor element and a surface opposite to the electrode terminal formation surface; and cutting the metal wire in a state of extending the metal wire to the side surface of the semiconductor element and the surface opposite to the electrode terminal formation surface.

In a semiconductor apparatus according to the invention, plural semiconductor elements in which metal wires whose one ends are connected to electrode terminals are extended to the side surfaces are stacked and at least a part of the metal wires extended to the side surfaces of the semiconductor elements is bonded to side surface wiring formed on side surfaces of the stacked semiconductor elements. As a result of this, a normal semiconductor element in which the electrode terminal is formed on only the one surface of the semiconductor element can be used.

Also, in the semiconductor apparatus according to the invention, a conductive paste containing conductive particles is applied and the side surface wiring is formed. Therefore, the side surface wiring can surely and easily be bonded to at least a part of the metal wires extended to the side surfaces of the semiconductor elements, and the side surface wiring can easily be formed as compared with a related-art semiconductor apparatus in which a side surface wiring is formed using a vapor deposition method and a liftoff method.

In the case of making contact between the metal wire and the conductive paste thus, wettability between the metal wire and the conductive paste is good, so that the conductive paste tends to be gathered on a peripheral surface of the metal wire and contact with the adjacent side surface wiring can be avoided and reliability of the finally obtained semiconductor apparatus can be improved.

Other features and advantages may be apparent from the following detailed description, the accompanying drawings and the claims.

### BRIEF DESCRIPTION OF THE DRAWINGS

FIG. 1 is a schematic sectional view explaining one example of a semiconductor apparatus according to the invention.

FIG. 2 is a process view of a part of the manufacturing steps of a semiconductor element constructing the semiconductor apparatus shown in FIG. 1.

FIGS. 3A to 3C are the other process views of the manufacturing steps of the semiconductor element constructing the semiconductor apparatus shown in FIG. 1.

FIGS. 4A and 4B are explanatory views explaining a comparative example with respect to the manufacturing steps shown in FIG. 2.

FIG. 5 is a schematic sectional view explaining a formation method for forming a side surface circuit on side surfaces of plural semiconductor elements stacked.

FIG. 6 is a schematic sectional view explaining a state of mounting the semiconductor apparatus shown in FIG. 1 on a circuit substrate.

FIG. 7 is a schematic sectional view explaining another example of a semiconductor apparatus according to the invention.

FIGS. 8A and 8B are process views of a manufacturing step of a semiconductor element constructing the semiconductor apparatus shown in FIG. 7.

FIG. 9 is a schematic sectional view explaining other example of a semiconductor apparatus according to the invention.

FIG. 10 is a process view of a manufacturing step of a semiconductor element constructing the semiconductor apparatus shown in FIG. 9.

FIG. 11 is a schematic view explaining a related-art semiconductor apparatus.

FIG. 12 is a perspective view explaining one example of an improved semiconductor apparatus.

FIG. 13 is a schematic view explaining another example of an improved semiconductor apparatus.

### DETAILED DESCRIPTION

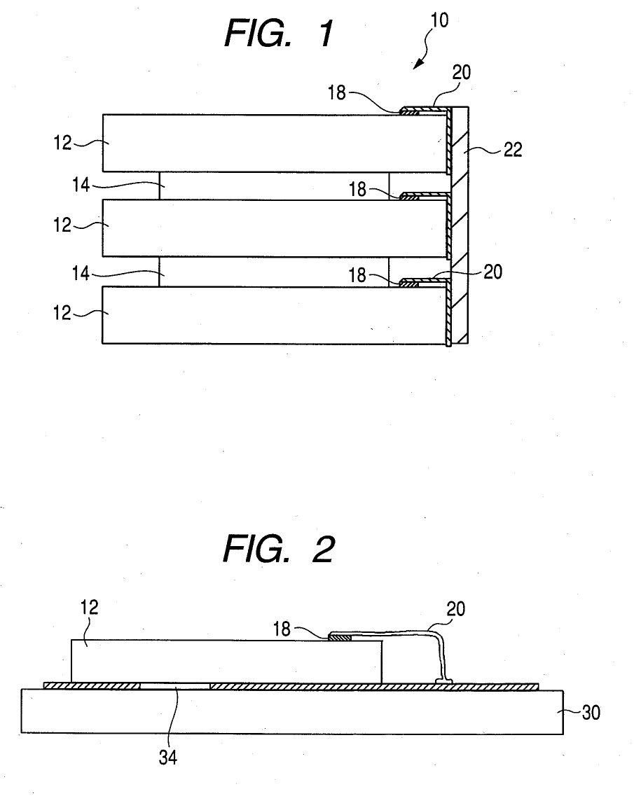

FIG. 1 shows one example of a semiconductor apparatus according to the invention. In a semiconductor apparatus 10 shown in FIG. 1, semiconductor elements 12, 12, 12 are stacked through adhesive layers 14 so that each of surfaces on which electrode terminals 18 of the semiconductor elements (which is referred as the electrode terminal formation surfaces) are formed is turned in the same direction (faces to an upper surface).

A gold wire 20 as a metal wire is connected to each of the electrode terminals 18 of such semiconductor elements 12, 12, 12, and the gold wire 20 is extended to the side surface of the semiconductor element 12. The gold wire 20 extended to the side surface of this semiconductor element 12 is in a state of abutment on the side surface of the semiconductor element 12.

In this manner, the gold wire 20 extended to each of the side surfaces of the semiconductor elements 12, 12, 12 is bonded to side surface wiring 22 formed on the side surfaces of the semiconductor elements 12, 12, 12 by a conductive paste containing conductive particles such as silver particles, copper particles or carbon particles.

Therefore, in the semiconductor apparatus 10 shown in FIG. 1, the normal semiconductor element 12 in which the electrode terminal 18 is formed on only the one surface can be used and it is unnecessary to use the semiconductor element of special specifications used in the semiconductor apparatus 200, 300 shown in FIG. 12 or FIG. 13.

Further, the conductive paste containing the conductive particles is applied and the side surface wiring 22 is formed, and the side surface wiring 22 can surely and easily be bonded to the portions of the gold wires 20 extended to the side surfaces of the semiconductor elements 12, 12, 12. Moreover, the side surface wiring can easily be formed as compared with a related-art semiconductor apparatus in which a side surface wiring is formed using a vapor deposition method and a liftoff method as described in the semiconductor apparatus 200 shown in FIG. 12.

Also, in the case of making contact between the gold wire 20 and the conductive paste, wettability between the gold wire 20 and the conductive paste is good, so that the conductive paste tends to be gathered on a peripheral surface of the gold wire 20 and contact with the adjacent side surface wiring 22 can be avoided.

In the case of manufacturing the semiconductor apparatus 10 shown in FIG. 1, it is first necessary to form the semiconductor element 12 in which the gold wire 20 whose one end is connected to the electrode terminal 18 is extended to the side surface.

In order to form such a semiconductor element 12, as shown in FIG. 2, metal foil 32 such as aluminum foil is placed on an adsorption plate 30 and also the semiconductor element 12 is placed on a through hole 34 formed in the metal foil 32. The semiconductor element 12 placed on the metal foil 32 is placed so that the electrode terminal formation surface on which the electrode terminal 18 of the semiconductor element is formed faces to an upper surface.

Further, this metal foil 32 and the semiconductor element 12 are respectively fixed in predetermined positions in predetermined places of the adsorption plate 30 by developing adsorption force of the adsorption plate 30. In this case, the semiconductor element 12 is adsorbed and fixed in the predetermined place of the adsorption plate 30 through the through hole 34 of the metal foil 32.

In this manner, after one end of the gold wire 20 is connected to the vicinity of the semiconductor element 12 of the metal foil 32 fixed by the adsorption force of the adsorption plate 30 by means of a wire bonder, the gold wire 20 is pulled out of a capillary and the other end of the gold wire 20 is connected to the electrode terminal 18 of the semiconductor element 12 and is torn.

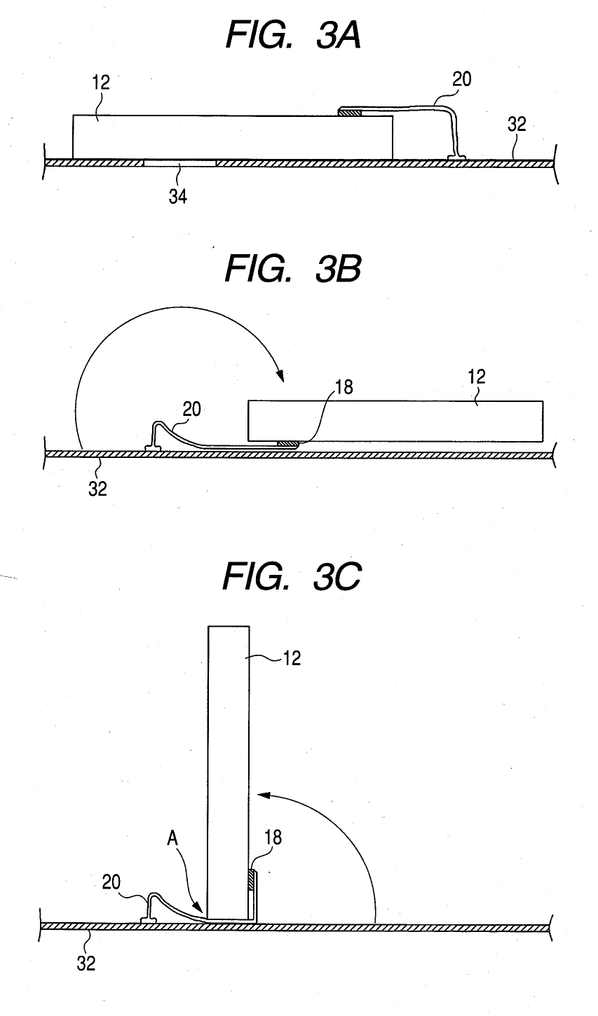

Next, as shown in FIG. 3A, adsorption of the adsorption plate +is released and the semiconductor element 12 and the metal foil =are taken out of the adsorption plate 30. When the adsorption of the adsorption plate 30 is released, the semiconductor element can be moved.

As a result of this, as shown in FIG. 3B, the semiconductor element 12 is rotated 180° and the electrode terminal formation surface is constructed so as to be turned in a direction (lower surface direction) of the metal foil 32.

Then, as shown in FIG. 3C, after the semiconductor element 12 is rotated 90° and is returned so that a side surface of the side of the electrode terminal 18 to which one end of the gold wire 20 of the semiconductor element 12 is connected abuts on the gold wire 20, the gold wire 20 is cut in a place (arrow A shown in FIG. 3C) of the vicinity of a surface opposite to the electrode terminal formation surface of the semiconductor element 12. Therefore, the semiconductor element 12 in which the gold wire 20 whose one end is connected to the electrode terminal 18 is extended to the side surface in an abutment state can be obtained.

By the way, wire bonding of the gold wire 20 shown in FIG. 2 is performed in a direction from the metal foil 32 to the electrode terminal 18 of the semiconductor element 12, by the so-called shooting up method. According to the wire bonding of the shooting up method thus, a rise in the gold wire 20 on the electrode terminal 18 of the semiconductor element 12 can be minimized. As a result of this, when the semiconductor element 12 is rotated 180° and the electrode terminal formation surface is turned in the direction (lower surface direction) of the metal foil 32 as shown in FIG. 3B, the gold wire 20 of the vicinity of the electrode terminal 18 can be prevented from being crushed by the metal foil 32.

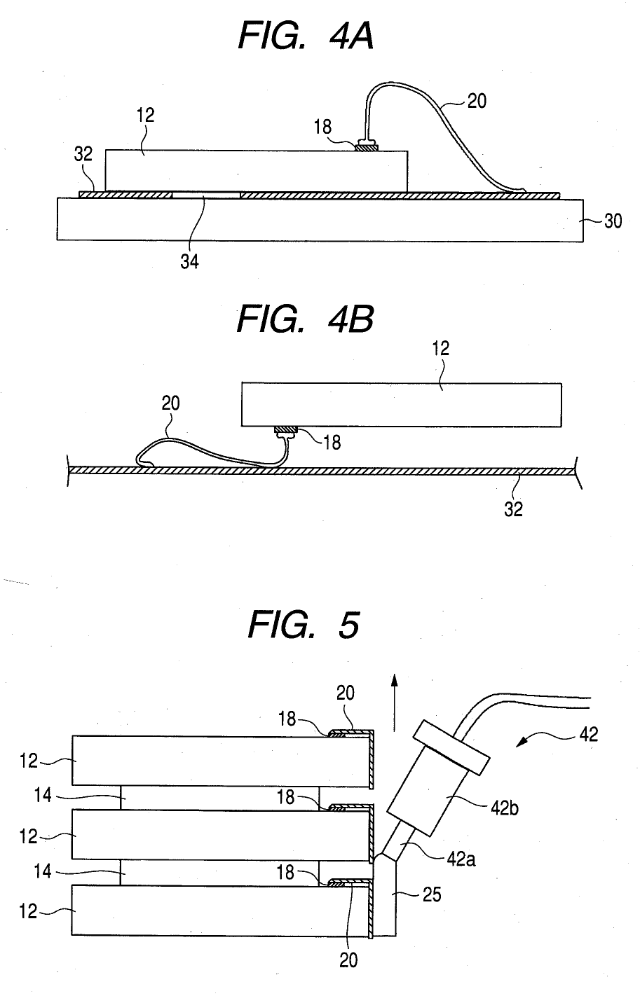

On the other hand, when the gold wire 20 is bonded in a direction from the electrode terminal 18 of the semiconductor element 12 to the metal foil 32, by the so-called fall method as shown in FIG. 4A, a rise in the gold wire 20 on the electrode terminal 18 of the semiconductor element 12 increases. As a result of this, when the semiconductor element 12 is rotated 180° and the electrode terminal formation surface is turned in a direction (lower surface direction) of the metal foil 32 as shown in FIG. 4B, the gold wire 20 of the vicinity of the electrode terminal 18 is crushed by the metal foil 32. The crushed gold wire 20 may make contact with the gold wire 20 whose one end is connected to the adjacent electrode terminal 18.

The plural semiconductor elements 12, 12, 12 obtained by cutting the gold wires 20 in a step shown in FIG. 3C, in which the gold wires 20 whose one ends are connected to the electrode terminals 18 are extended to the side surfaces in the abutment state, are stacked through the adhesive layers 14, 14 so that each of the electrode terminal formation surfaces on which the electrode terminals 18 are formed is turned in the same direction as shown in FIG. 5. In this case, positions of the semiconductor elements 12, 12, 12 are adjusted so that the gold wires 20 extended to each of the side surfaces of the semiconductor elements 12, 12, 12 become straight.

Then, a conductive paste 25 containing conductive particles such as silver particles, copper particles or carbon particles is applied along the gold wires 20 extended to each of the side surfaces of the semiconductor elements 12, 12, 12. This conductive paste 25 is applied by being discharged from a nozzle 42a to the side surfaces of the stacked semiconductor elements 12, 12, 12 by a gas pressure such as a nitrogen pressure from a filling bath 42b filled with the conductive paste constructing an applicator 42. In this case, the conductive paste 25 can be formed on the side surfaces of the semiconductor elements 12, 12, 12 in a strip shape by moving the applicator 42 from the lower portion to the upper portion (direction of an arrow shown in FIG. 5) of the stacked semiconductor elements 12, 12, 12. The gold wires 20, 20, 20 abutting on the side surfaces of the semiconductor elements 12, 12, 12 are included in this strip-shaped conductive paste 25.

Thereafter, by heat-treating the strip-shaped conductive paste 25, a semiconductor apparatus in which the side surface wiring 22 to which the gold wires 20, 20, 20 abutting on the side surfaces of the semiconductor elements 12, 12, 12 are bonded is formed as shown in FIG. 1 can be formed.

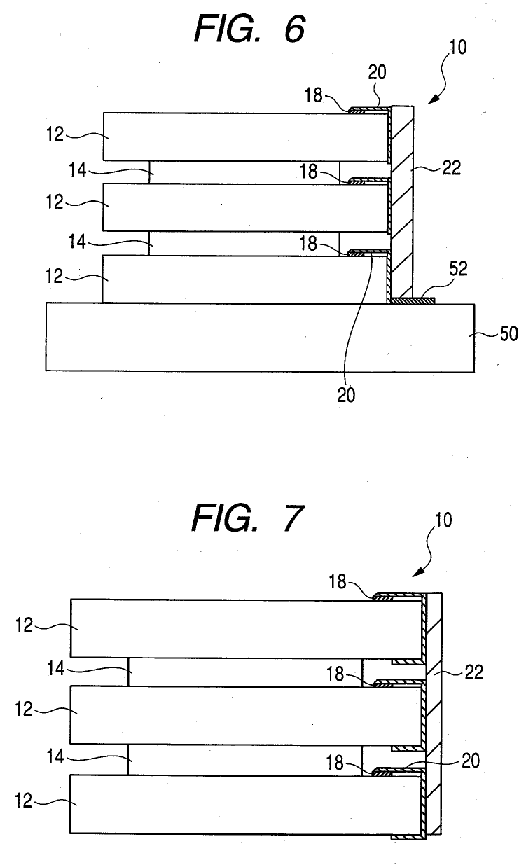

The semiconductor apparatus 10 shown in FIG. 1 may be mounted on a circuit substrate 50 as shown in FIG. 6 and in this case, it is installed so as to make connection between a pad 52 of the circuit substrate 50 and the side surface wiring 22 of the semiconductor apparatus 10.

In the semiconductor element 12 constructing the semiconductor apparatus 10 shown in FIG. 1, the gold wire 20 is extended to the side surface of the semiconductor element 12 in the abutment state, but a gold wire 20 extended to a side surface of a semiconductor element 12 in an abutment state may be extended to a surface opposite to an electrode terminal formation surface on which an electrode terminal 18 of the semiconductor element 12 is formed as shown in FIG. 7.

In order to form the semiconductor element 12 shown in FIG. 7, as shown in FIG. 2, the semiconductor element 12 is placed on a through hole 34 of metal foil 32 placed on an adsorption plate 30 and one end of the gold wire 20 is connected to the vicinity of the semiconductor element 12 of the metal foil 32 fixed by developing adsorption force of the adsorption plate 30 by means of a wire bonder and thereafter, the gold wire 20 is pulled out of a capillary and the other end of the gold wire 20 is connected to the electrode terminal 18 of the semiconductor element 12 and is torn.

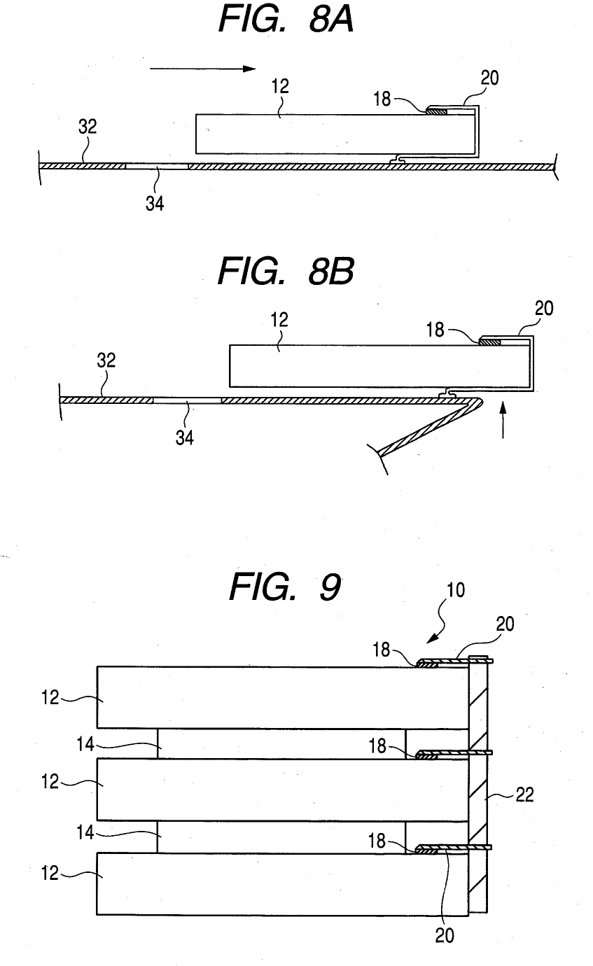

Then, after adsorption of the adsorption plate 30 is released and the semiconductor element 12 and the metal foil 32 are taken out of the adsorption plate 30 as shown in FIG. 3A, the semiconductor element 12 is slid in a direction of the gold wire 20 and the side surface of the semiconductor element 12 is abutted on the gold wire 20 so that the gold wire 20 traverses in a state of abutment on the side surface of the semiconductor element 12 as shown in FIG. 8A.

The semiconductor element 12 of a state shown in FIG. 8A can be obtained by rotating the semiconductor element 12 erected vertically to the metal foil 32 90° so that the electrode terminal formation surface of the semiconductor element 12 faces to an upper surface as shown in FIG. 3C.

Thereafter, as shown in FIG. 8B, a part of the metal foil 32 is folded and the gold wire 20 extended to the surface opposite to the electrode terminal formation surface of the semiconductor element 12 is exposed and the portion (portion shown by an arrow of FIG. 8B) of the vicinity of the side surface of the opposite surface of the gold wire 20 extended to the opposite surface is cut by a cutter etc. The semiconductor element 12 in which the gold wire 20 whose one end is connected to the electrode terminal 18 traverses in a state of close contact with the side surface and is extended to the surface opposite to the electrode terminal formation surface can be obtained.

By the way, in the case of sliding the semiconductor element 12 and extending the gold wire 20 to the side surface of the semiconductor element 12 as shown in FIG. 8A, the gold wire 20 may be torn in the corner of the surface opposite to the electrode terminal formation surface of the semiconductor element 12. In the case of tearing the gold wire 20 thus, the gold wire 20 can easily be cut in a predetermined place by previously scratching the predetermined place of the gold wire 20 by a clip etc.

The plural semiconductor elements 12, 12, 12 in which the gold wires 20 whose one ends are connected to the electrode terminals 18 traverse in a state of abutment on the side surfaces and are extended to the surfaces opposite to the electrode terminal formation surfaces are stacked through the adhesive layers 14, 14 so that each of the electrode terminal formation surfaces on which the electrode terminals 18 are formed is turned in the same direction as shown in FIG. 5. In this case, positions of the semiconductor elements 12, 12, 12 are adjusted so that the gold wires 20 extended to each of the side surfaces of the semiconductor elements 12, 12, 12 become straight.

Then, a strip-shaped conductive paste 25 can be formed on the side surfaces of the stacked semiconductor elements 12, 12, 12 by discharging a conductive paste containing conductive particles from a nozzle 42a of an applicator 42 along the gold wires 20 extended to each of the side surfaces of the semiconductor elements 12, 12, 12.

Thereafter, by heat-treating the strip-shaped conductive paste 25, side surface wiring 22 can be formed on the side surfaces of the stacked semiconductor elements 12, 12, 12 as shown in FIG. 7.

In the semiconductor apparatuses 10 shown in FIGS. 1 and 7, the gold wire 20 whose one end is connected to the electrode terminal 18 is extended in the state of abutment on each of the side surfaces of the constructed semiconductor elements 12, 12, 12, but as shown in FIG. 9, a semiconductor element 12 in which the other end of a gold wire 20 whose one end is connected to an electrode terminal 18 protrudes to the side surface can be used.

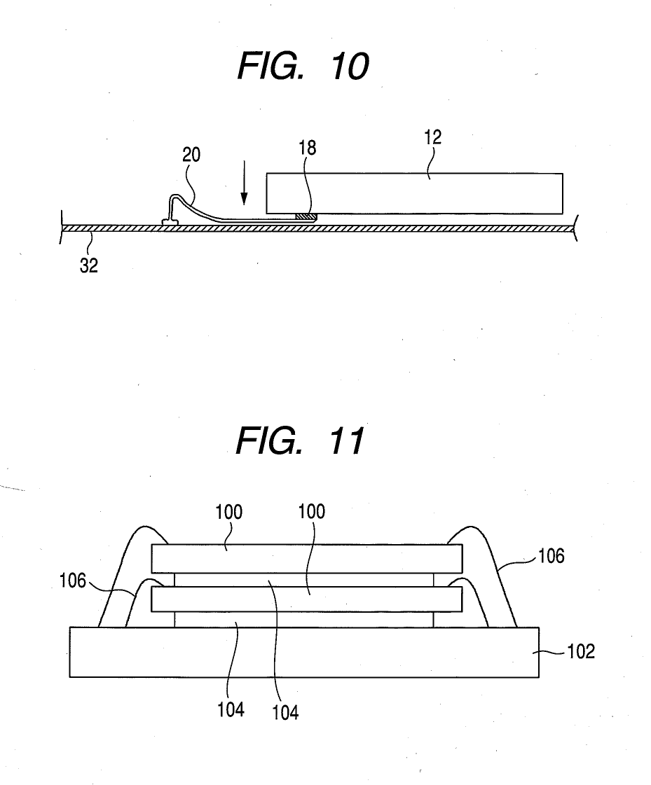

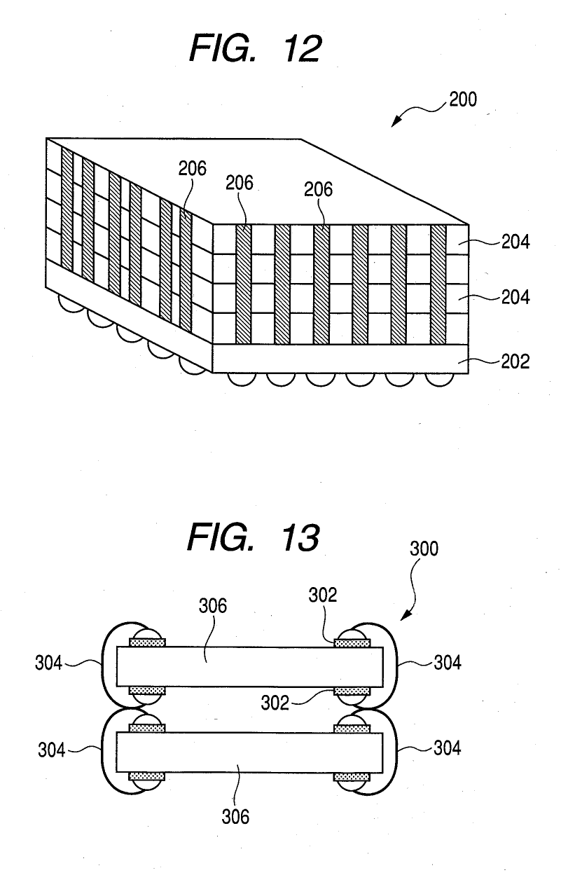

Such a semiconductor element 12 can be obtained by cutting the portion (portion shown by an arrow in FIG. 10) of the vicinity of the side surface and the portion in which a straight portion of the gold wire 20 protrudes from the side surface of the semiconductor element 12 as shown in FIG. 10 by a cutter etc. in a state in which the semiconductor element 12 is rotated 180° and an electrode terminal formation surface is turned in a direction (lower surface direction) of metal foil 32 as shown in FIG. 3B.

The gold wire 20 extended to the side surface of the semiconductor element 12 shown in FIGS. 1 to 8 described above could be extended to the side surface of the semiconductor element 12, and it is not always necessary to abut the gold wire 20 on the side surface of the semiconductor element 12.

What is claimed is:

1. A semiconductor apparatus comprising:
a plurality of semiconductor elements which are stacked;
metal wires, each of which is connected to each of electrode terminals of the semiconductor elements at one end and is extended to the side surfaces of the semiconductor elements; and
a side surface wiring formed on the side surfaces of the stacked semiconductor elements by a conductive paste containing conductive particles,
wherein at least a part of the metal wires extended to the side surfaces of the semiconductor elements is bonded to the side surface wiring.

2. A semiconductor apparatus as claimed in claim 1, wherein the metal wire is extended to the side surface of the semiconductor element by performing a wire bonding by a shooting up method including connecting the other end of the metal wire to a metal foil in which the semiconductor element is installed so that an electrode terminal formation surface on which the electrode terminal is formed faces to an upper surface and then connecting the one end of the metal wire to the electrode terminal of the semiconductor element.

3. A semiconductor apparatus as claimed in claim 1, wherein the metal wire is extended to a surface opposite to an electrode terminal formation surface on which the electrode terminal is formed beyond the side surface of the semiconductor element.

4. A semiconductor apparatus as claimed in claim 1, wherein the metal wire is extended in a state of being abutted on at least the side surface of the semiconductor element.

5. A manufacturing method of a semiconductor apparatus, comprising:
stacking a plurality of semiconductor elements in which metal wires are connected to electrode terminals at one ends are extended to side surfaces of the semiconductor elements, through an adhesive layer; and
applying a conductive paste the side surfaces of the stacked semiconductor elements and forming a side surface wiring to which at least a part of the metal wires extended to the side surfaces of the semiconductor elements is bonded.

6. A manufacturing method of a semiconductor apparatus as claimed in claim 5, further comprising:
installing the semiconductor element on a metal foil so that an electrode terminal formation surface on which the electrode terminal is formed faces to an upper surface;
performing a wire bonding of the metal wire by a shooting up method including connecting the other end of the metal wire to the metal foil and then connecting the one end of the metal wire to the electrode terminal of the semiconductor element;
rotating the semiconductor element so as to abut the metal wire on the side surface of the semiconductor element; and
cutting the metal wire in a state of extending the metal wire to the side surface of the semiconductor element.

7. A manufacturing method of a semiconductor apparatus as claimed in claim 5, further comprising:
installing the semiconductor element on a metal foil so that an electrode terminal formation surface on which the electrode terminal is formed faces to an upper surface;
performing a wire bonding of the metal wire by a shooting up method including connecting the other end of the metal wire to the metal foil and then connecting the one end of the metal wire to the electrode terminal of the semiconductor element;
sliding the semiconductor element so as to abut the metal wire on the side surface of the semiconductor element; and
cutting the metal wire in a state of extending the metal wire to the side surface of the semiconductor element.

8. A manufacturing method of a semiconductor apparatus as claimed in claim 5, further comprising:
installing the semiconductor element on a metal foil so that an electrode terminal formation surface on which the electrode terminal is formed faces to an upper surface;
performing a wire bonding of the metal wire by a shooting up method including connecting the other end of the metal wire to the metal foil and then connecting the one end of the metal wire to the electrode terminal of the semiconductor element;
rotating the semiconductor element is rotated so as to abut the metal wire on the side surface of the semiconductor element and a surface opposite to the electrode terminal formation surface; and
cutting the metal wire in a state of extending the metal wire to the side surface of the semiconductor element and the surface opposite to the electrode terminal formation surface.
